(19) United States
(12) Patent Application Publication
(10) Pub. No.: US 2026/0114271 A1
(43) Pub. Date: Apr. 23, 2026

(54) DEEP TRENCH MIM CAPACITOR STRUCTURE AND METHOD OF MANUFACTURING THEREOF

(71) Applicant: Taiwan Semiconductor Manufacturing Company, Ltd., Hsinchu (TW)

(72) Inventors: Ke-Jing Yu, New Taipei City (TW); Anhao Cheng, Hsinchu (TW); Yen-Liang Lin, Yilan County (TW); Ping-Pang Hsieh, Hsinchu (TW)

(73) Assignee: Taiwan Semiconductor Manufacturing Company, Ltd., Hsinchu (TW)

(21) Appl. No.: 18/918,655

(22) Filed: Oct. 17, 2024

(51) Int. Cl. H01L 23/522

(52) U.S. Cl. CPC H10W 20/496

(57) ABSTRACT

A capacitor structure includes at least two first bottom metal vias vertically over a substrate; a first bottom metal layer over and in contact with the first bottom metal vias; and a deep trench capacitor over the first bottom metal layer. The deep trench capacitor includes a bottom electrode over and in contact with a top surface of the first bottom metal layer; a top electrode over the bottom electrode; and a dielectric layer between the bottom electrode and the top electrode. The bottom electrode at a level adjacent to the top surface of the first bottom metal layer laterally defines a first area having a first rectangular shape. The first bottom metal layer laterally defines a second area larger than the first area and laterally covering the first area.

### BACKGROUND

Capacitors of different categories, such as metal insulator metal (MIM) capacitors, are widely used in data manipulation and data storage applications. In order to reduce the size of a MIM capacitor, a deep trench MIM capacitor can be used. However, a deep trench MIM capacitor may suffer from issues like reliability issue. Thus, an improved deep trench MIM capacitor structure is desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagrammatic cross-sectional side view of a semiconductor system including a deep trench MIM capacitor circuit and a control circuit in accordance with some embodiments.

FIG. 2 is a top view of a conventional deep trench MIM capacitor structure, and FIG. 3 is a cross-sectional side view of the conventional deep trench MIM capacitor structure in FIG. 2, which are used to illustrate connection failures suffered by the conventional deep trench MIM capacitor structure.

FIG. 4 is a diagrammatic cross-sectional side view of a deep trench MIM capacitor circuit in accordance with some embodiments.

FIG. 5 is a top view of a deep trench MIM capacitor structure in FIG. 4, and FIG. 6 is a cross-sectional side view of the deep trench MIM capacitor structure in FIG. 5 in accordance with a first embodiment.

FIG. 7 is a top view of a deep trench MIM capacitor structure in FIG. 4, and FIG. 8 is a cross-sectional side view of the deep trench MIM capacitor structure in FIG. 7 in accordance with a second embodiment.

FIG. 9 is a top view of a deep trench MIM capacitor structure in FIG. 4, and FIG. 10 is a cross-sectional side view of the deep trench MIM capacitor structure in FIG. 9 in accordance with a third embodiment.

FIG. 11 is a top view of a deep trench MIM capacitor structure in FIG. 4, and FIG. 12 is a cross-sectional side view of the deep trench MIM capacitor structure in FIG. 11 in accordance with a fourth embodiment.

FIG. 13 is a top view of a deep trench MIM capacitor structure in FIG. 4, and FIG. 14 is a cross-sectional side view of the deep trench MIM capacitor structure in FIG. 13 in accordance with a fifth embodiment.

FIGS. 15, 16, 17, 18 and 19 are top views of a deep trench MIM capacitor structure in FIG. 4 in accordance with a first, a second, a third, a fourth, and a fifth embodiments, respectively.

FIG. 20 illustrates a flow chart of an example method of manufacturing a deep trench MIM capacitor structure in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Capacitors are widely used components for many data manipulation and data storage applications. In general, capacitors include two conductive electrodes on opposing sides of a dielectric or other insulating layer, and can be categorized based on the materials employed to form the electrodes. For example, in a metal-insulator-metal (MIM) capacitor, the electrodes are substantially metal. To minimize sizes, deep trench (or cup-shaped) capacitor structures located in capacitor openings can be used. A capacitor opening can be etched through a stop layer to expose a contact plug thereunder, and over-etching is performed to ensure the capacitor opening is fully defined in every cell areas over a semiconductor wafer. When there is an overlay shift of the capacitor opening, the over-etching produces a micro-trench under the capacitor opening which may adversely affect reliability. In comparison with a planar MIM transistor, a deep trench MIM capacitor can have an increased capacitance within a given space. However, a deep trench MIM structure may land on a small bottom metal layer and can be connected to a logic circuit though the bottom metal layer and a small metal via, can cause high stress on the small bottom metal layer and high thermal effect e.g., in a deposition process, and thus can induce stress migration and electron migration on the bottom metal layer and the bottom metal via underneath, thereby causing reliability issues, such as resistant shift, even open issues on the bottom metal layer and/or the bottom metal via. An improved deep trench MIM capacitor structure is thus desired.

In accordance with some embodiments of the present disclosure, a deep trench metal insulator metal (MIM) capacitor structure includes at least two first bottom metal vias disposed over a substrate; a first bottom metal layer disposed over and in contact with the first bottom metal vias; a deep trench disposed over the first bottom metal layer; and a capacitor formed within the deep trench. The MIM capacitor includes a bottom electrode having a bottom portion over and in contact with a top surface of the first bottom metal layer; a top electrode over the bottom electrode; and a dielectric layer disposed between the bottom electrode and the top electrode. The bottom electrode of the MIM capacitor at a level adjacent to the top surface of the first bottom metal layer laterally defines a first area having a first rectangular shape, and the first bottom metal layer laterally defines a second area that is larger than the first area and laterally covers the first area. The first bottom metal vias are laterally within the second area. In some embodiments, the second area defined by the first bottom metal layer has a second rectangular shape, and the at least two first bottom metal vias are laterally within the first area, or laterally outside the first area but within the second area. In other embodiments, the second area defined by the first bottom metal layer includes a first sub-area and a second sub-area respectively having different rectangular shapes and laterally in contact with each other, the first area defined by the bottom electrode of the MIM capacitor is laterally within the first sub-area B1 and the first bottom metal vias are laterally within the second sub-area B2.

As such, the deep trench MIM capacitor structure of the present application avoids small bottom metal line corner turn connections in the first bottom metal layer disposed under and in contact with the bottom electrode of the capacitor, increases redundant first bottom metal vias (e.g., there are two or more first bottom metal vias) disposed under and in contact with the first bottom metal layer, and thus advantageously minimizes void and/or broken line impacts in the first bottom metal layer and the first bottom metal vias, thereby leading to improved quality of the deep trench MIM capacitor structure.

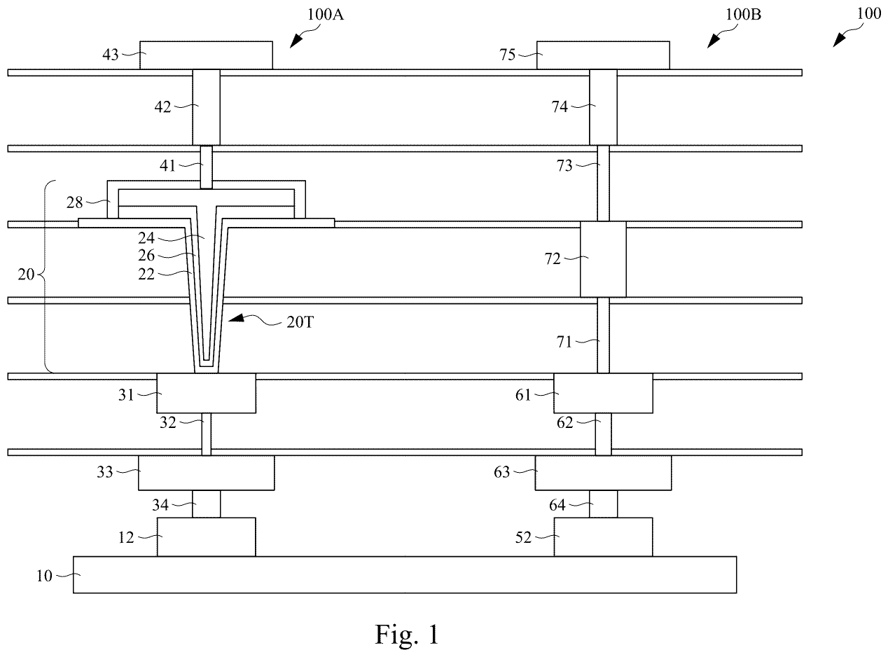

FIG. 1 is a diagrammatic cross-sectional side view of a semiconductor system 100 including at least one capacitor circuit 100A and a control circuit 100B in accordance with some embodiments. The semiconductor system 100 can be configured as a system-on-chip (SoC) device that integrates various functions on a single chip. The capacitor circuit 100A and a control circuit 100B are each configured for a different function. For example, the capacitor circuit 100A can form a dynamic random access memory (DRAM) array for memory storage, and the control circuit 100B may function as a logic control circuit used to control the capacitor circuit 100A. It is understood that the semiconductor system 100 may include other features and structures such as inductors, passivation layers, bonding pads, and packaging, but is simplified in FIG. 1 for the sake of simplicity and clarity.

In some embodiments, the capacitor circuit 100A includes a substrate 10, a first transistor 12 formed on the substrate 10, and a deep trench MIM capacitor 20, which is coupled to the first transistor 12 through a plurality of bottom metal lines or layers (such as a first bottom metal layer 31 and a second bottom metal layer 33), and a plurality of bottom metal vias (such as a first bottom metal via 32 and a second bottom metal via 34). The MIM capacitor 20 can be used for various functions such as high-frequency noise filtering in mixed-signal applications. It may also be used in memory applications, oscillators, phase-shift networks, bypass filters, and as a coupling capacitor in radio frequency (RF) applications. As shown in FIG. 1, the deep trench MIM capacitor 20 can be formed in a deep trench 20T disposed over the first bottom metal layer 31, and includes a bottom electrode 22 over and in contact with a top surface of the first bottom metal layer 31, a top electrode 24 over the bottom electrode 22, and a dielectric layer 26 between them. In some embodiments, the deep trench MIM capacitor 20 includes a capping layer 28 over and in contact with the top electrode 24. In some embodiments, the capacitor circuit 100A also includes a plurality of top metal vias (such as a first top via 41), a plurality of top metal lines or layers (such as a first top metal layer 42), and a top contact pad 43. More details about the capacitor circuit 100A will be further described with reference to FIG. 4.

In some embodiments, the control circuit 100B includes a second transistor 52 formed on the substrate 10, a plurality of bottom metal lines or layers (such as 61 and 63) and bottom metal vias (such as 62 and 64), a plurality of top metal lines or layers (such as 72 and 74) and top metal vias (such as 71 and 73), and a top contact pad 73, and can control the capacitor circuit 100A. In some embodiments, the deep trench MIM capacitor 20 is coupled to the control circuit 100B through the first bottom metal layer 31, through the first bottom metal vias 32, the second bottom metal layer 33, the second bottom metal via 34, the first transistor 12, and the second transistor 52, and thus can be controlled by the control circuit 100B.

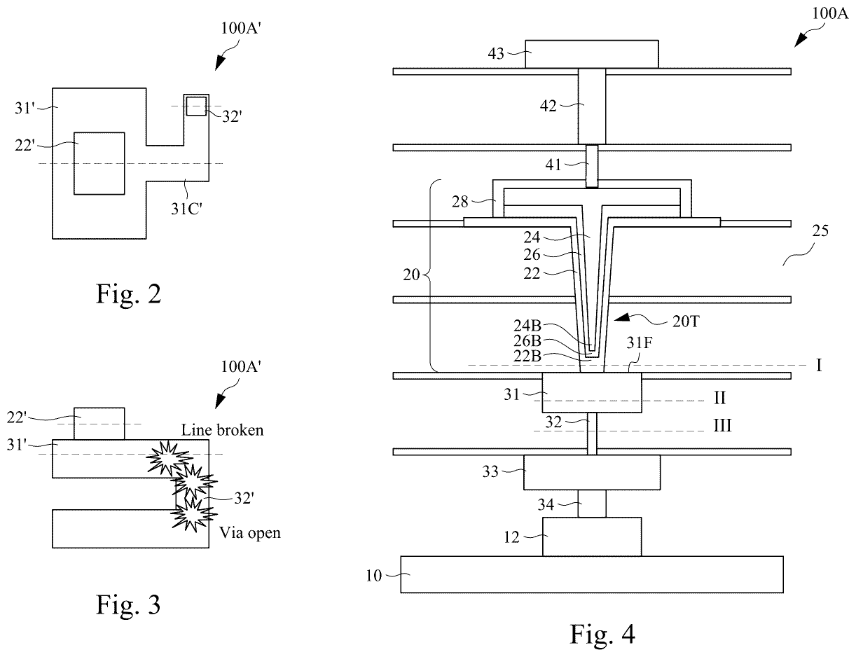

FIG. 2 is a top view of a conventional MIM capacitor structure 100A′, and FIG. 3 is a cross-sectional side view of the deep trench MIM capacitor structure 100A′ in FIG. 2, illustrating connection failures suffered by the deep trench MIM capacitor structure 100A′. FIG. 2 is a top perspectival view, showing three planes, at three different levels, of the bottom electrode 22′, a bottom metal layer 31′ with a connection portion 31C′, and the bottom metal via 32′, which can be respectively taken along three lines I, II and III (in FIG. 4). The MIM capacitor structure 100A′ includes a bottom electrode 22′, a top electrode (not shown), and a dielectric layer (not shown) therebetween. Referring to FIG. 2 and FIG. 3, the bottom electrode 22′ of the MIM capacitor structure 100A′ lands on a top surface of a bottom metal layer 31 with a connection portion 31C′, which has at least one narrow corner turn portion in its top-view profile, and lands on and laterally covers a single bottom metal via 32′ thereunder. Due to high stress caused by the capacitor structure 100A′ and high thermal effects during fabrication processes, the bottom metal layer 31′ and the bottom metal via 32′ may suffer connection failures, such as broken line failures and open via failures, thereby causing the capacitor structure 100A′ to suffer from connection failures.

FIG. 4 is a diagrammatic cross-sectional side view of a deep trench MIM capacitor circuit 100A in accordance with some embodiments. As aforementioned with reference to FIG. 1, the capacitor circuit 100A includes a substrate 10, a first transistor 12 formed on the substrate 10, and a deep trench MIM capacitor 20, which is coupled to the first transistor 12 through a plurality of bottom metal layers (such as a first bottom metal layer 31 and a second bottom metal layer 33) and a plurality of bottom metal vias (such as a first bottom metal via 32 and a second bottom metal via 34). In some embodiments, the substrate 10 includes a silicon substrate (e.g., wafer) in a crystalline structure. The substrate 10 may include various doping configurations depending on design requirements as is known in the art (e.g., p-type substrate or n-type substrate). Additionally, the substrate 10 may include various doped regions such as p-type wells (p-wells) or n-type wells (n-wells). Such a doped region defines an oxide definition (OD) region. The substrate 10 may also include other elementary semiconductors such as germanium and diamond. Alternatively, the substrate 10 may include a compound semiconductor such as silicon carbide, gallium arsenide, indium arsenide, or indium phosphide. Further, the substrate 10 may optionally include an epitaxial layer (epi-layer), may be strained for performance enhancement, and may include a silicon-on-insulator (SOI) structure.

In some embodiments, the deep trench MIM capacitor 20 is formed in a deep trench 20T that is formed over the first bottom metal layer 31. In some embodiments, the deep trench MIM capacitor 20 includes a bottom electrode 22 formed over and in contact with a top surface of the first bottom metal layer 31, a top electrode 24 formed over the bottom electrode 22, and a dielectric layer 26 between them. In some embodiments, as shown in FIG. 4, the deep trench MIM capacitor 20 is cup-shaped. In some embodiments, the bottom electrode 22 includes a side portion, and a bottom portion 22B in contact with a top surface of the first bottom metal layer 31; the dielectric layer 26 includes a side portion in contact with the side portion of the bottom electrode 22, and a bottom portion 26B in contact with the bottom portion 22B of the bottom electrode 22; and the top electrode 24 includes a side portion in contact with the side portion of the dielectric layer 26, and a bottom portion 24B in contact with the bottom portion 26B of the dielectric layer 26. In some embodiments, the deep trench MIM capacitor 20 further includes a capping layer 28 over and in contact with the top electrode 24. In some embodiments, the capacitor circuit 100A includes a plurality of top metal lines or layers (such as a first top metal layer 41), a plurality of top metal vias (such as a first top via 41), and a top contact pad 43.

In some embodiments, the first transistor 12 is poly gate transistor, and in other embodiments, the first transistor 12 is metal gate transistor. In some embodiments, the bottom electrode 22 and the top electrode 24 are made of a material selected from such as TiN and TaN. In some embodiments, the dielectric layer 26 is made of a high-K metal oxide material selected from such as ZrOx, AlOx, and HfOx. In some embodiments, the bottom metal layers and vias (such as 31, 32, 33, and 34) and the top metal layers and vias (such as 41 and 42) are made of materials selected from copper, tungsten, aluminum, cobalt, silver, gold, chrome, ruthenium, platinum, titanium, titanium nitride, tantalum, tantalum nitride, nickel, hafnium, and combinations thereof. In some embodiments, the capping layer 28 is made of a material selected from such as SIN, oxide, SION, and a combination thereof. In some embodiments, the top contact pad 43 is made of a material of aluminum doping copper (e.g., with 3-5% copper).

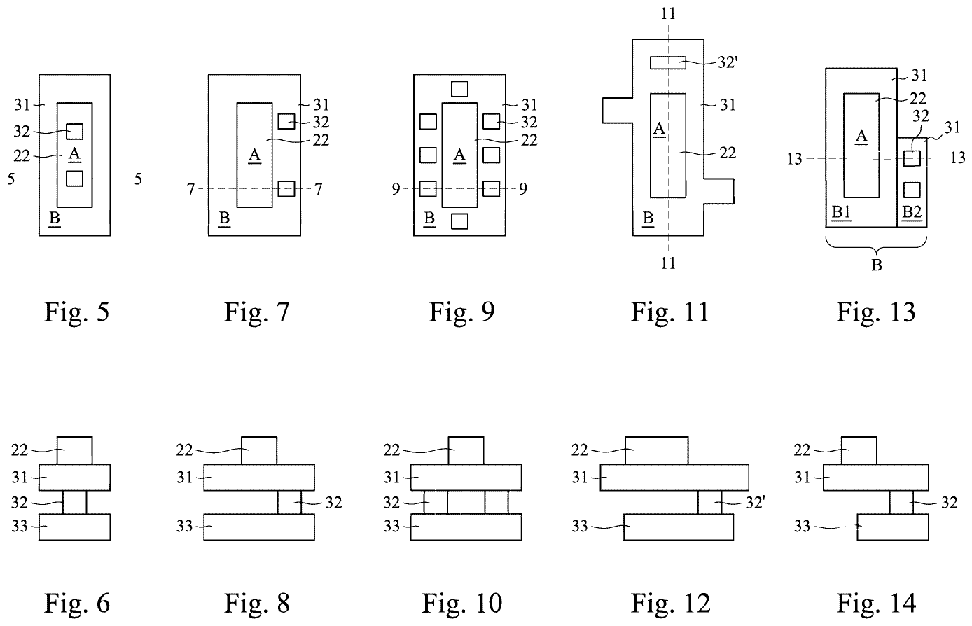

FIGS. 5, 7, 9, 11 and 13 are top views of various example deep trench MIM capacitor structures in accordance with various embodiment of the present application, and FIGS. 6, 8, 10, 12 and 14 are cross-sectional side views of the various example deep trench MIM capacitor structures in FIGS. 5, 7, 9, 11 and 13 in accordance with various embodiment of the present application.

FIG. 5 is a top perspectival view of an example deep trench MIM capacitor structure in FIG. 4, showing three planes of a bottom electrode 22, a bottom metal layer 31 without any connection portion, and at least one bottom metal via 32, respectively taken along three lines I, II and III as shown in FIG. 4, and FIG. 6 is a cross-sectional side view of the deep trench MIM capacitor structure in FIG. 5 taken along a line 5-5 in accordance with a first embodiment. In some embodiments, referring to FIG. 4, the deep trench MIM capacitor 20 includes a bottom electrode 22 formed over and in contact with a top surface of the first bottom metal layer 31, a top electrode 24 formed over the bottom electrode 22, and a dielectric layer 26 between them. In some embodiments, also referring to FIG. 4, the bottom portion 22B of the bottom electrode 22 lands on the first bottom metal layer 31, which in turn lands on two or more first bottom metal vias 32, which in turn land on a second bottom metal layer 33. In some embodiments, referring to FIGS. 4, 5 and 6, the bottom electrode 22 at a level adjacent to the top surface 31F of the first bottom metal layer 31 laterally defines a first area A having a first rectangular shape, and the first bottom metal layer 31 laterally defines a second area B that has a second rectangular shape, is larger than the first area A, and laterally covers the first area A. In some embodiments, as shown in FIGS. 5 and 6, the two or more first bottom metal vias 32 are disposed laterally within the first area A defined by the bottom portion 22B of the bottom electrode 22 and are laterally separated from each other.

FIG. 7 is a top view of an example deep trench MIM capacitor structure in FIG. 4, showing three planes of a bottom electrode 22, a bottom metal layer 31 without any connection portion, and at least one bottom metal via 32, respectively taken along three lines I, II and III as shown in FIG. 4, and FIG. 8 is a cross-sectional side view of the deep trench MIM capacitor structure in FIG. 7 taken along a line 7-7 in accordance with a second embodiment. Similarly, in some embodiments, referring to FIG. 4, the deep trench MIM capacitor 20 includes a bottom electrode 22 formed over and in contact with a top surface of the first bottom metal layer 31, a top electrode 24 formed over the bottom electrode 22, and a dielectric layer 26 between them. In some embodiments, also referring to FIG. 4, the bottom portion 22B of the bottom electrode 22 lands on the first bottom metal layer 31, which in turn lands on two or more first bottom metal vias 32, which in turn land on a second bottom metal layer 33. In some embodiments, referring to FIGS. 4, 7 and 8, the bottom electrode 22 at a level adjacent to the top surface 31F of the first bottom metal layer 31 laterally defines a first area A having a first rectangular shape, and the first bottom metal layer 31 laterally defines a second area B that has a second rectangular shape, is larger than the first area A, and laterally covers the first area A. In some embodiments, as shown in FIGS. 7 and 8, two first bottom metal vias 32 are disposed laterally separated from each other, laterally outside the first area A defined by the bottom portion 22B of the bottom electrode 22, and laterally within the second area B defined by the top surface of the first bottom metal layer 31. In some embodiments, as shown in FIGS. 7 and 8, the two first bottom metal vias 32 are laterally parallel with and adjacent to a side of the second area B.

FIG. 9 is a top view of an example deep trench MIM capacitor structure in FIG. 4, showing three planes of a bottom electrode 22, a bottom metal layer 31 without any connection portion, and at least one bottom metal via 32, respectively taken along three lines I, II and III as shown in FIG. 4, and FIG. 10 is a cross-sectional side view of the deep trench MIM capacitor structure in FIG. 9 taken along a line 9-9 in accordance with a third embodiment. Similarly, in some embodiments, referring to FIG. 4, the deep trench MIM capacitor 20 includes a bottom electrode 22 formed over and in contact with a top surface of the first bottom metal layer 31, a top electrode 24 formed over the bottom electrode 22, and a dielectric layer 26 between them. In some embodiments, also referring to FIG. 4, the bottom portion 22B of the bottom electrode 22 lands on the first bottom metal layer 31, which in turn lands on two or more first bottom metal vias 32, which in turn land on a second bottom metal layer 33. In some embodiments, referring to FIGS. 4, 9 and 10, the bottom electrode 22 at a level adjacent to the top surface 31F of the first bottom metal layer 31 laterally defines a first area A having a first rectangular shape, and the first bottom metal layer 31 laterally defines a second area B that has a second rectangular shape, is larger than the first area A, and laterally covers the first area A. In some embodiments, as shown in FIGS. 9 and 10, more than two (e.g., eight) first bottom metal vias 32 are disposed laterally separated from each other, laterally outside and around the first area A defined by the bottom portion 22B of the bottom electrode 22, and laterally within the second area B defined by the top surface of the first bottom metal layer 31.

FIG. 11 is a top view of an example deep trench MIM capacitor structure in FIG. 4, showing three planes of a bottom electrode 22, a bottom metal layer 31 without any connection portion, and at least one bottom metal via 32, respectively taken along three lines I, II and III as shown in FIG. 4, and FIG. 12 is a cross-sectional side view of the deep trench MIM capacitor structure in FIG. 11 taken along a line 11-11 in accordance with a fourth embodiment. Similarly, in some embodiments, referring to FIG. 4, the deep trench MIM capacitor 20 includes a bottom electrode 22 formed over and in contact with a top surface of the first bottom metal layer 31, a top electrode 24 formed over the bottom electrode 22, and a dielectric layer 26 between them. In some embodiments, also referring to FIG. 4, the bottom portion 22B of the bottom electrode 22 lands on the first bottom metal layer 31, which in turn lands on two or more first bottom metal vias 32, which in turn land on a second bottom metal layer 33. In some embodiments, referring to FIGS. 4, 9 and 10, the bottom electrode 22 at a level adjacent to the top surface 31F of the first bottom metal layer 31 laterally defines a first area A having a first rectangular shape, and the first bottom metal layer 31 laterally defines a second area B that has a second rectangular shape, is larger than the first area A, and laterally covers the first area A. In some embodiments, as shown in FIGS. 11 and 12, two or more first bottom metal vias 32 are laterally in contact with each other and form a combined bottom metal via 32′ that is laterally within the first area A defined by the bottom electrode 22.

FIG. 13 is a top view of an example deep trench MIM capacitor structure in FIG. 4, showing three planes of a bottom electrode 22, a bottom metal layer 31 without any connection portion, and at least one bottom metal via 32, respectively taken along three lines I, II and III as shown in FIG. 4, and FIG. 14 is a cross-sectional side view of the deep trench MIM capacitor structure in FIG. 13 taken along a line 13-13 in accordance with a fifth embodiment. Similarly, in some embodiments, referring to FIG. 4, the deep trench MIM capacitor 20 includes a bottom electrode 22 formed over and in contact with a top surface of the first bottom metal layer 31, a top electrode 24 formed over the bottom electrode 22, and a dielectric layer 26 between them. In some embodiments, also referring to FIG. 4, the bottom portion 22B of the bottom electrode 22 lands on the first bottom metal layer 31, which in turn lands on two or more first bottom metal vias 32, which in turn land on a second bottom metal layer 33. In some embodiments, referring to FIGS. 4, 13 and 14, the bottom electrode 22 at a level adjacent to the top surface 31F of the first bottom metal layer 31 laterally defines a first area A having a first rectangular shape, and the first bottom metal layer 31 laterally defines a second area B. In some embodiments, different from the first, the second, the third, and the fourth embodiments, as shown in FIGS. 13 and 14, the second area B includes a first sub-area B1 and a second sub-area B2 that having different rectangular shapes and laterally in contact with each other, the first sub-area B1 being larger than the second sub-area B2. In some embodiments, the first area A is laterally within the first sub-area B1, and the first bottom metal vias 32 are laterally within the second sub-area B2.

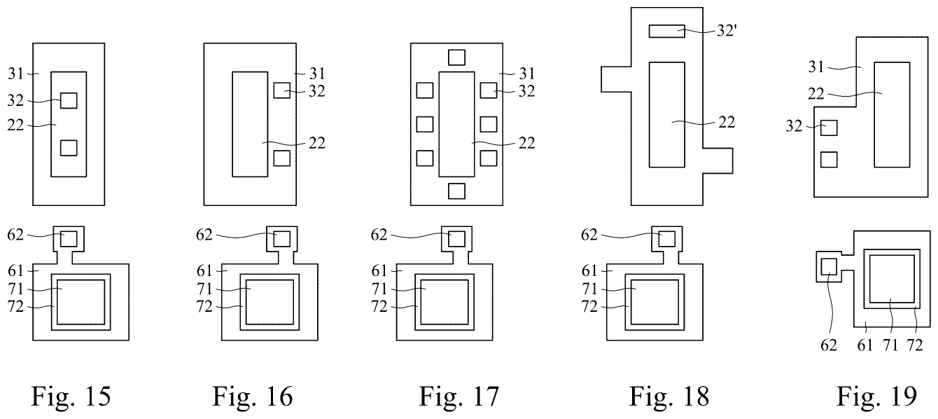

Referring to e.g., FIGS. 5, 7, 9 and 11, in some embodiments, the ratio of the area of A to the area of B is in a range from about 0.2 to about 0.8, and the ratio of the area of the vias 32 to the area of A is in a range from about 0.005 to about 0.2. Referring to e.g., FIG. 13, in some embodiments, the ratio of the area of A to the area of (B1+B2) is in a range from about 0.2 to about 0.8, and the ratio of the area of the vias 32 to the area of A is in a range from about 0.005 to about 0.2. Referring to e.g., FIGS. 5, 7, 9 and 11, in some embodiments, the width of A is in a range from about 100 nm to about 500 nm, and the length of A is in a range from about 500 nm to about 2 μm, the width of B is in a range from about 120 nm to about 600 nm, and the length of B is in a range from about 600 nm to about 2.2 μm. In some embodiments, e.g., as shown in FIGS. 5, 7 and 9, the via 32 is in a square shape with four sides of the same length, which is in a range from about 20 nm to about 50 nm, and the number of the vias 32 is two or greater than two. In other embodiments, e.g., as shown in FIG. 11, the via 32 is in a rectangular shape having a length that is in a range from about 40 nm to about 100 nm, and a width that is in a range from about 20 nm to about 50 nm, and the number of the via(s) 32 is one (or greater than one, not shown). Referring to FIG. 13, in some embodiments, the width of A is in a range from about 100 nm to about 500 nm, the length of A is in a range from about 500 nm to about 2 μm, the width of B1 is in a range from about 120 nm to about 600 nm, the length of B1 is in a range from about 600 nm to about 2.2 μm, the width of B2 is in a range from about 50 nm to about 250 nm, the length of B2 is in a range from about 100 nm to about 1 μm, the length of each side of the square shaped vias 32 is in a range from about 20 nm to about 50 nm, and the number of the vias 32 is two or greater than two. FIGS. 15, 16, 17, 18 and 19 are top views of portions of the capacitor circuit 100A and portions of the control circuit 100B in FIG. 1 in accordance with a first, a second, a third, a fourth, and a fifth embodiments, respectively, which illustrate various arrangements of such as a bottom electrode 22, a first bottom metal line 31, and a first bottom metal via 32 of the capacitor circuit 100A, as well as a first bottom metal line 61, a first bottom metal via 62, a second top metal via 71, and a second top metal line 72 of the control circuit 100B. As shown in FIGS. 1, 15, 16, 17, 18 and 19, the bottom electrode 22 of a MIM capacitor 20 of the capacitor circuit 100A is coupled to a second top metal line 72 of the control circuit 100B through a first bottom metal line 31, a first bottom metal via 32, a second bottom metal line 33, a second bottom metal via 34, a first transistor 12 of the capacitor circuit 100A, as well as a second transistor 52, a second bottom metal via 64, a second bottom metal line 63, a first bottom metal via 62, a first bottom metal line 61, and a second top metal via 71 of the control circuit 100B.

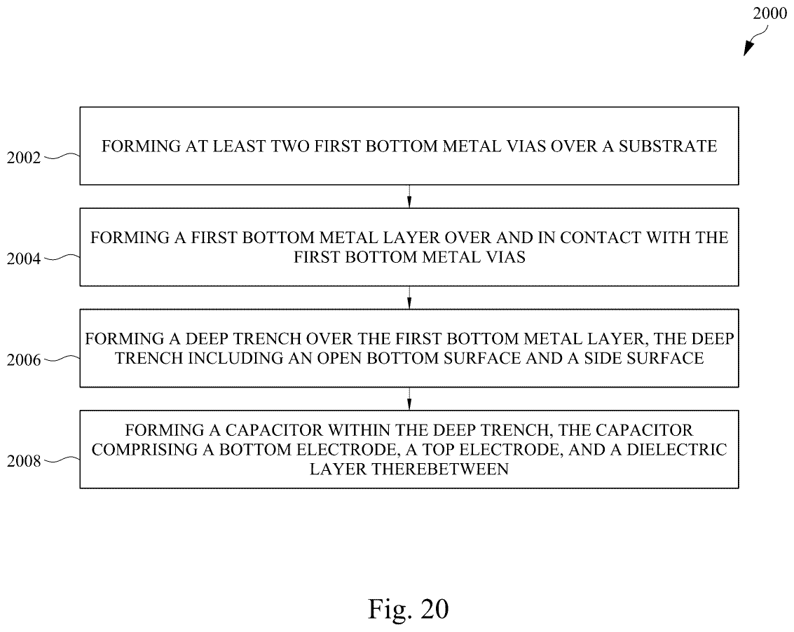

FIG. 20 illustrates a flow chart of an example method 2000 of manufacturing a deep trench MIM capacitor structure 100A as shown in FIG. 4 in accordance with various embodiments. It is understood that additional operations can be provided before, during, and after processes discussed in FIG. 20, and some of the operations described below can be replaced or eliminated, for additional embodiments of the method. The order of the operations/processes may be interchangeable and at least some of the operations or processes may be performed in a different sequence. In some embodiments, at least two or more operations or processes are performed overlapping in time, or almost simultaneously.

In some embodiments, as shown in FIG. 1, a plurality of transistors (such as a first transistor 12 and a second transistor 52) are formed on a substate 10 in a FEOL network. Various methods of oxidation, photolithography, deposition, and etching for example can be used to form the plurality of transistors. In some embodiments, the substrate 10 includes a single crystalline semiconductor layer on at least its surface portion. The substrate may include a single crystalline semiconductor material such as, but not limited to Si, Ge, SiGe, GaAs, InSb, GaP, GaSb, InAlAs, InGaAs, GaSbP, GaAsSb and InP. In some embodiments, the substrate 10 is silicon wafer. The substrate 10 may include in its surface region, one or more buffer layers (not shown). The buffer layers can serve to gradually change the lattice constant from that of the substrate to that of the source/drain regions.

As shown in FIGS. 4-14 and FIG. 20, in some embodiments, operation 2002 includes forming at least two first bottom metal vias 32 over the substrate 10. Various methods of photolithography, etching, and deposition can be used to form the at least two first bottom metal vias 32. In some embodiments, prior to forming the at least two first bottom metal vias 32, a plurality of second bottom metal vias 34 are formed over and coupled to the first transistor 12, and a second bottom metal layer 33 is then formed over and in contact with the plurality of second bottom metal vias 34. In some embodiments, the at least two first bottom metal vias 32 are formed over and in contact with the second bottom metal layer 33.

Next, shown in FIGS. 4-14 and FIG. 20, in some embodiments, operation 2004 includes forming a first bottom metal layer 31 over and in contact with the first bottom metal vias 32. Various methods of photolithography, etching, and deposition can be used to form the first bottom metal layer 31. In some embodiments, the inter-connect lines or layers (such as the first metal layer 31 and the second metal layer 33) and inter-connect vias (such as the first metal via 32 and the second metal via 34) are made of materials selected from copper, tungsten, aluminum, cobalt, silver, gold, chrome, ruthenium, platinum, titanium, titanium nitride, tantalum, tantalum nitride, nickel, hafnium, and combinations thereof.

Next, shown in FIG. 4 and FIG. 20, in some embodiments, operation 2006 includes forming a deep trench 20T over the first bottom metal layer 31 within an inter-layer dielectric (ILD) 25, the deep trench 20T having an open bottom surface and a side surface. Various methods of photolithography, etching, and deposition processes can be used to form the deep trench 20T within the ILD 25.

Next, shown in FIGS. 4-14 and FIG. 20, in some embodiments, operation 2008 includes forming a capacitor 20 within the deep trench 20T. The capacitor 20 includes a bottom electrode 22, a top electrode 24, and a dielectric layer 26 between the bottom electrode 22 and the top electrode 24. In some embodiments, forming the capacitor 20 within the deep trench 20T includes forming a bottom electrode 22 that includes a bottom portion 22B in contact with the top surface 31F of the first bottom metal layer 31 and a vertical portion in contact with the side surface of the trench 20T, forming a dielectric layer 26 that includes a bottom portion 26B in contact with the bottom portion 22B of the bottom electrode 22 and a vertical portion in contact with the vertical portion of the bottom electrode 22, and forming the top electrode 24 that includes a bottom portion 24B in contact with the bottom portion 26B of the dielectric layer 26 and a vertical portion in contact with the vertical portion of the dielectric layer 26. In some embodiments, the bottom electrode 22 and the top electrode 24 are made of a material selected from such as TiN and TaN. In some embodiments, the dielectric layer 26 is made of a high-K metal oxide material selected from such as ZrOx, AlOx, and HfOx.

In some embodiments, as shown in FIG. 4, a capping layer 28 is formed over and in contact with the top electrode 24. In some embodiments, as shown in FIG. 4, a capping layer 28 is formed over the top electrode 24, and in contact with sides of the top electrode 24 and the dielectric layer 26. In some embodiments, the capping layer 28 is made of a material selected from such as SIN, oxide, SION, and a combination thereof.

In some embodiments, as shown in FIG. 4, at least one first top metal via 41 is formed over and in contact with the capping layer 28, at least one first top metal line or layer 42 is formed over and in contact with the at least one first top metal via 41, and at least one top contact pad 43 is formed over and in contact with the at least one first top metal line or layer 42. In some embodiments, the first top metal via 41, the first top metal line or layer 42, and the top contact pad 43 are made of Cu, W, Al, and a combination thereof. In some embodiments, the top contact pad 43 is made of a material of Al doping Cu (e.g., with 3-5% Cu).

In some embodiments, as aforementioned with reference to FIGS. 5-14, which illustrate the spatial relationship of the bottom electrode 22 of the capacitor 20, the first bottom metal layer 31 under the bottom electrode 22, and the first bottom metal via 32 under the first bottom metal layer 31, the bottom electrode 22 of the capacitor 20 at a level adjacent to a top surface of the first bottom metal layer 31 laterally defines a first area A having a rectangular shape, and the first bottom metal layer 31 laterally defines a second area B being larger than and laterally covering the first area A.

In some embodiments, as shown in FIGS. 5-12, the second area B defined by the first bottom metal layer 31 has a rectangular shape, and laterally covering the first area A defined by the bottom electrode 22 of the capacitor 20. In some embodiments, as shown in FIGS. 5-6, the first bottom metal vias 32 are laterally disposed within the first area A defined by the bottom electrode 22 of the capacitor 20. In some embodiments, as shown in FIGS. 7-10, the first bottom metal vias 32 are laterally disposed within the second area B defined by the first bottom metal layer 31, but outside the first area A defined by the bottom electrode 22 of the capacitor 20. In some embodiments, at least two first bottom metal vias 31 are laterally in contact with each other to form a combined bottom metal via 31′ that is laterally within the second area B defined by the first bottom metal layer 31, but outside the first area A defined by the bottom electrode 22 of the capacitor 20.

In other embodiments, as shown in FIGS. 13-14, the second area B defined by the first bottom metal layer 31 has a first sub-area B1 of a rectangular shape and a second sub-area B2 of a rectangular shape, which are laterally in contact with each other side by side. In some embodiments, the first area A defied by the bottom electrode 22 of the capacitor 20 is laterally within the first sub-area B1 of the second area B, and the bottom metal vias 32 are laterally within the second sub-area B2 of the second area B.

As such, the deep trench MIM capacitor structure or circuit 100A of the present application reduces or avoids small bottom metal line corner turn connections in the first bottom metal layer 31 disposed under and in contact with the bottom electrode 22 of the capacitor lands, increases redundant first bottom metal vias 32 disposed under and in contact with the first bottom metal layer 31, and thus advantageously minimizes void impacts in the first bottom metal layer 31 and the first bottom metal vias 32, thereby leading to improved quality of the capacitor structure or circuit.

In one aspect of the present disclosure, a capacitor structure includes: at least two first bottom metal vias disposed vertically over a substrate; a first bottom metal layer disposed over and in contact with the first bottom metal vias; a deep trench disposed over the first bottom metal layer; and a capacitor formed within the deep trench. The capacitor includes: a bottom electrode over and in contact with a top surface of the first bottom metal layer; a top electrode over the bottom electrode; and a dielectric layer disposed between the bottom electrode and the top electrode. The bottom electrode at a level adjacent to the top surface of the first bottom metal layer laterally defines a first area having a first rectangular shape, and the first bottom metal layer laterally defines a second area larger than the first area and laterally covering the first area.

In another aspect of the present disclosure, a capacitor structure includes: at least two first bottom metal vias disposed over a substrate; a first bottom metal layer disposed over and in contact with the first bottom metal vias; a deep trench capacitor formed over the first bottom metal layer. The deep trench capacitor includes a bottom electrode including a bottom portion in contact with a top surface of the first bottom metal layer, and a vertical portion; a dielectric layer including a bottom portion in contact with the bottom portion of the bottom electrode, and a vertical portion in contact with the vertical portion of the bottom electrode; and a top electrode in contact with the bottom portion and the vertical portion of the dielectric layer. The bottom electrode of the capacitor laterally defines a first area having a first rectangular shape, and the first bottom metal layer laterally defines a second area larger than and laterally covering the first area.

In yet another aspect of the present disclosure, a method of manufacturing a capacitor structure includes: forming at least two first bottom metal vias over a substrate; forming a first bottom metal layer over and in contact with the first bottom metal vias; forming a deep trench over the first bottom metal layer, the deep trench comprising an open bottom surface and a side surface; and forming a capacitor within the deep trench. The capacitor includes a bottom electrode, a top electrode, and a dielectric layer between the bottom electrode and the top electrode. The bottom electrode of the capacitor at a level adjacent to a top surface of the first bottom metal layer laterally defines a first area having a first rectangular shape, and the first bottom metal layer laterally defines a second area larger than and laterally covering the first area.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A capacitor structure, comprising:
at least two first bottom metal vias disposed vertically over a substrate;
a first bottom metal layer disposed over and in contact with the at least two first bottom metal vias;
a deep trench disposed over the first bottom metal layer; and
a capacitor formed within the deep trench and comprising:
a bottom electrode over and in contact with a top surface of the first bottom metal layer;
a top electrode over the bottom electrode; and
a dielectric layer disposed between the bottom electrode and the top electrode,
wherein the bottom electrode at a level adjacent to the top surface of the first bottom metal layer laterally defines a first area having a first rectangular shape, and
wherein the first bottom metal layer laterally defines a second area larger than the first area and laterally covering the first area.

2. The capacitor structure of claim 1, wherein the at least two first bottom metal vias are laterally within the second area.

3. The capacitor structure of claim 1, wherein the second area has a second rectangular shape.

4. The capacitor structure of claim 1, wherein the second area consists of a first sub-area and a second sub-area that have different rectangular shapes and are laterally in contact with each other, the first sub-area being larger than the second sub-area.

5. The capacitor structure of claim 4, wherein the first area is laterally within the first sub-area, and wherein the at least two first bottom metal vias are laterally within the second sub-area.

6. The capacitor structure of claim 1, wherein the at least two first bottom metal vias are laterally in contact with each other to form a combined bottom metal via laterally within the second area but outside the first area.

7. The capacitor structure of claim 1, wherein the at least two first bottom metal vias are laterally disposed within the first area.

8. The capacitor structure of claim 1, wherein the at least two first bottom metal vias are laterally disposed within the second area but outside the first area.

9. The capacitor structure of claim 1, wherein the bottom electrode of the capacitor is coupled to a first transistor through a back contact, and wherein the first transistor is coupled to a second transistor of a control circuit.

10. The capacitor structure of claim 1, further comprising:
a capping layer disposed over and in contact with the top electrode of the capacitor.

11. The capacitor structure of claim 10, further comprising:
a first top metal via disposed over and in contact with the capping layer;
a first top metal layer disposed over and in contact with the first top metal via; and
a top contact disposed over and in contact with the first top metal layer.

12. A capacitor structure, comprising:
at least two first bottom metal vias disposed over a substrate;
a first bottom metal layer disposed over and in contact with the at least two first bottom metal vias;
a deep trench capacitor formed over the first bottom metal layer, and comprising:
a bottom electrode including a first bottom portion in contact with a top surface of the first bottom metal layer, and a first vertical portion;
a dielectric layer including a second bottom portion in contact with the first bottom portion of the bottom electrode, and a second vertical portion in contact with the first vertical portion of the bottom electrode; and
a top electrode in contact with the second bottom portion and the second vertical portion of the dielectric layer,
wherein the bottom electrode of the deep trench capacitor laterally defines a first area having a first rectangular shape, and
wherein the first bottom metal layer laterally defines a second area larger than and laterally covering the first area.

13. The capacitor structure of claim 12, wherein the second area laterally covers the at least two first bottom metal vias.

14. The capacitor structure of claim 12, wherein the second area has a second rectangular shape.

15. The capacitor structure of claim 12, wherein the at least two first bottom metal vias are laterally covered by the first area.

16. The capacitor structure of claim 12, wherein the at least two first bottom metal vias are laterally covered by the second area but laterally beyond the first area.

17. A method of manufacturing a capacitor structure, comprising:
forming at least two first bottom metal vias over a substrate;
forming a first bottom metal layer over and in contact with the at least two first bottom metal vias;
forming a deep trench over the first bottom metal layer, the deep trench comprising an open bottom surface and a side surface; and
forming a capacitor within the deep trench, the capacitor comprising a bottom electrode, a top electrode, and a dielectric layer between the bottom electrode and the top electrode,
wherein the bottom electrode of the capacitor at a level adjacent to a top surface of the first bottom metal layer laterally defines a first area having a first rectangular shape, and
wherein the first bottom metal layer laterally defines a second area larger than and laterally covering the first area.

18. The method of claim 17, wherein the second area has a second rectangular shape, and wherein the at least two first bottom metal vias are laterally covered by the second area.

19. The method of claim 17, wherein the second area consists of a first sub-area of a second rectangular shape and a second sub-area of a third rectangular shape laterally in contact with each other side by side, and wherein the first area is laterally within the first sub-area of the second area and the at least two first bottom metal vias is laterally within the second sub-area of the second area.

20. The method of claim 17, wherein the forming of the capacitor within the deep trench comprises:
forming the bottom electrode including a first bottom portion in contact with the top surface of the first bottom metal layer, and a first vertical portion in contact with the side surface of the deep trench;
forming the dielectric layer including a second bottom portion in contact with the first bottom portion of the bottom electrode, and a second vertical portion in contact with the first vertical portion of the bottom electrode; and
forming the top electrode disposed in contact with the second bottom portion and the second vertical portion of the dielectric layer.
